(19) United States
(12) Patent Application Publication
(10) Pub. No.: US 2026/0293664 A1
(43) Pub. Date: Sep. 24, 2026

(54) SEMICONDUCTOR DEVICE INCLUDING STACKED DEEP TRENCH CAPACITOR STRUCTURE

(71) Applicant: DB HiTek Co., Ltd., Bucheon-si (KR)

(72) Inventor: Chang Hun HAN, Icheon-si (KR)

(21) Appl. No.: 19/209,288

(22) Filed: May 15, 2025

(30) Foreign Application Priority Data
Mar. 19, 2025 (KR) 10-2025-0035238

(51) Int. Cl. H01L 23/522; H01L 21/768

(52) U.S. Cl. CPC H10W 20/496; H10W 20/046; H10W 20/42

(57) ABSTRACT

A semiconductor device including a stacked deep trench capacitor structure is configured such that a pad metal is formed in a capacitor area where a deep trench capacitor is formed, thereby reducing equivalent series resistance (ESR) of a capacitor, and improving device properties such as switching speed, high band frequency properties, and the like.

### CROSS REFERENCE TO RELATED APPLICATION

The present application claims priority to Korean Patent Application No. 10-2025-0035238, filed Mar. 19, 2025, the entire contents of which are incorporated herein for all purposes by this reference.

### BACKGROUND OF THE INVENTION

### Field of the Invention

The present disclosure relates to a semiconductor device including a stacked deep trench capacitor structure and a method for manufacturing the same. More particularly, the present disclosure relates to a semiconductor device including a stacked deep trench capacitor structure and a method for manufacturing the same, wherein a pad metal is formed in a capacitor area where a deep trench capacitor is formed, thereby reducing equivalent series resistance (ESR) of a capacitor, and improving device properties such as switching speed, high band frequency properties, and the like.

### Description of the Related Art

The semiconductor industry has continued to develop semiconductor devices with reduced surface area to form a large number of devices on the same-sized substrate. The vertical device structure can significantly reduce surface area requirements for a large number of semiconductor devices. One type of vertical device commonly implemented on integrated chips is deep trench capacitors. The deep trench capacitors include one or more capacitor electrodes extending into a trench in a semiconductor substrate. The deep trench capacitors may be used for a variety of purposes, for example, as a decoupling capacitor configured to decouple one part of an electrical circuit, such as an interconnect, from another part of the circuit.

In order to increase the capacitance value per unit area of the deep trench capacitor as described above, a method of bonding two wafers in which the deep trench capacitor is formed may be considered. In order to connect the two wafers, a pad metal has to be located on an outer portion of a chip, which increases the size of the chip and increases the equivalent series resistance (ESR) of the capacitor, which is a problem.

To solve the above-mentioned problems, the inventor of the present disclosure proposes a semiconductor device including a new type of stacked deep trench capacitor structure and a manufacturing method thereof, the details of which will be described later.

### DOCUMENT OF RELATED ART

### Patent Document

(Patent Document 1) Korean Patent Application Publication No. 10-2021-0111931 “Trench capacitor”

### SUMMARY OF THE INVENTION

Accordingly, the present disclosure has been made keeping in mind the above problems occurring in the related art, and the present disclosure is intended to propose a semiconductor device including a deep trench capacitor structure and a method for manufacturing the same, wherein a first substrate and a second substrate where deep trench capacitors are formed are stacked on each other to increase a capacitance value per unit area of each capacitor area where each deep trench capacitor is formed.

Another objective of the present disclosure is to provide a semiconductor device including a stacked deep trench capacitor structure and a method for manufacturing the same, wherein pad metals are formed between a first substrate and a second substrate that are formed with deep trench capacitors stacked on each other, thereby reducing the equivalent series resistance (ESR) of a capacitor, and improving device properties such as switching speed, high band frequency properties, and the like.

Yet another objective of the present disclosure is to provide a semiconductor device including a stacked deep trench capacitor structure and a method for manufacturing the same, wherein a pad metal is formed on a second surface of a second substrate and electrically connected to another pad metal between a first substrate and the second substrate, thereby reducing equivalent series resistance (ESR) of a capacitor, and improving the device properties.

The present disclosure may be realized by embodiments having following configuration in order to achieve the above-described objective.

According to an embodiment of the present disclosure, there is provided a semiconductor device including a stacked deep trench capacitor structure according to the present disclosure including: a first capacitor area; a first wiring area on the first capacitor area; a second wiring area on the first wiring area; and a second capacitor area on the second wiring area, wherein the first capacitor area may include: a first substrate comprising a first surface and a second surface facing each other; and a first deep trench capacitor provided at the first substrate, and the second capacitor area may include: a second substrate comprising a first surface and a second surface facing each other; and a second deep trench capacitor at the second substrate.

According to another embodiment of the present disclosure, in the semiconductor device including a stacked deep trench capacitor structure of the present disclosure, the first wiring area may include: a first insulator film layer; a first pad metal in the first insulator film layer; and a first contact plug located in the first insulator film layer and electrically connecting the first pad metal and the first deep trench capacitor to each other.

According to another embodiment of the present disclosure, in the semiconductor device including a stacked deep trench capacitor structure of the present disclosure, the second wiring area may include: a second insulator film layer; a second pad metal in the second insulator film layer; and a second contact plug located in the second insulator film layer and electrically connecting the second pad metal and the second deep trench capacitor to each other.

According to another embodiment of the present disclosure, in the semiconductor device including a stacked deep trench capacitor structure of the present disclosure, the semiconductor device ay include: a pad area on the second capacitor area.

According to another embodiment of the present disclosure, in the semiconductor device including a stacked deep trench capacitor structure of the present disclosure, the pad area may include one portion connected to both the first pad metal and the second pad metal.

According to another embodiment of the present disclosure, in the semiconductor device including a stacked deep trench capacitor structure of the present disclosure, the pad area may include: a via hole penetrating the second substrate in a vertical direction; a through silicon via (TSV) extending downwards from an inner portion or a lower portion of the via hole and connected to both the first pad metal and the second pad metal; and a third pad metal filling the inner portion of the via hole.

According to another embodiment of the present disclosure, in the semiconductor device including a stacked deep trench capacitor structure of the present disclosure, the via hole may have a greater width size than a size of a deep trench of the second deep trench capacitor.

According to another embodiment of the present disclosure, in the semiconductor device including a stacked deep trench capacitor structure of the present disclosure, the pad area may include: a third insulator film layer on an inner side wall and a bottom surface of the via hole, and wherein the third insulator film layer is located between the third pad metal and the inner side wall of the via hole.

According to another embodiment of the present disclosure, in the semiconductor device including a stacked deep trench capacitor structure of the present disclosure, the insulator film layer may cover a portion of an upper surface of the second insulator film layer exposed at a lower portion of the via hole.

According to another embodiment of the present disclosure, in the semiconductor device including a stacked deep trench capacitor structure of the present disclosure, the pad area further may include: a connection metal on the third insulator film layer, wherein the connection metal may be connected to the TSV.

According to another embodiment of the present disclosure, there is provided a semiconductor device including a stacked deep trench capacitor structure according to the present disclosure including: a first substrate; a first deep trench extending from a first surface of the first substrate toward a second surface facing the first surface; a first conductive layer and a first dielectric layer deposited in the first deep trench successively; a first insulator film layer on the first substrate; a first pad metal and a second pad metal stacked on each other in the first insulator film layer in multiple steps; a second substrate on the first insulator film layer; a second deep trench extending from a first surface of the second substrate toward a second surface facing the first surface of the second substrate; and a second conductive layer and a second dielectric layer deposited in the second deep trench successively, wherein the first pad metal may be connected to the first conductive layer, and the second pad metal may be connected to the second conductive layer.

According to another embodiment of the present disclosure, in the semiconductor device including a stacked deep trench capacitor structure of the present disclosure, the semiconductor device may include: a via hole penetrating the second substrate; a second insulator film layer on the second substrate; a second pad metal on the second insulator film layer, and inside the via hole; and a TSV extending downwards from an inner portion or a lower portion of the via hole.

According to another embodiment of the present disclosure, in the semiconductor device including a stacked deep trench capacitor structure of the present disclosure, the TSV may be connected to both the first pad metal and the second pad metal.

According to another embodiment of the present disclosure, in the semiconductor device including a stacked deep trench capacitor structure of the present disclosure, the semiconductor device may include: a passivation layer provided in contact with the second pad metal on the second surface of the second substrate.

According to another embodiment of the present disclosure, in the semiconductor device including a stacked deep trench capacitor structure of the present disclosure, the TSV may extend to a position between an upper surface of the second insulator film layer on the second substrate and the second pad metal.

According to another embodiment of the present disclosure, there is provided a method for manufacturing a semiconductor device including a stacked deep trench capacitor structure, which includes a first capacitor area including a first substrate; a first wiring area including a first insulator film layer and provided on the first capacitor area; a second wiring area including a second insulator film layer and provided on the first wiring area; and a second capacitor area including a second substrate and provided on the second wiring area, the method including: forming a first via hole on the second substrate by etching the second substrate; forming an insulator film layer along an upper surface of the second substrate and an inner side wall of the first via hole; forming a TSV in a first insulator film layer and a second insulator film layer at a lower portion the first via hole; and forming a first pad metal on the second capacitor area.

According to another embodiment of the present disclosure, in the method for manufacturing the semiconductor device including a stacked deep trench capacitor structure of the present disclosure, the forming of the TSV may be performed by forming a second via hole in the first insulator film layer and the second insulator film layer; and gap-filling a metal layer in the second via hole.

According to another embodiment of the present disclosure, in the method for manufacturing the semiconductor device including a stacked deep trench capacitor structure of the present disclosure, the TSV may be connected to a second pad metal formed in each of the first insulator film layer and the second insulator film layer.

According to another embodiment of the present disclosure, in the method for manufacturing the semiconductor device including a stacked deep trench capacitor structure of the present disclosure, the first pad metal may extend to an inner portion of the first via hole and is connected to the TSV.

According to another embodiment of the present disclosure, in the method for manufacturing the semiconductor device including a stacked deep trench capacitor structure of the present disclosure, the second via hole may have a width size smaller than a width size of the first via hole.

The present disclosure has the following effects with the above-described configuration.

According to the present disclosure, the first substrate and the second substrate in which the deep trench capacitors are formed are stacked on each other, and the capacitance value per unit area of the capacitor area where each deep trench capacitor is formed can be increased.

Furthermore, according to the present disclosure, a pad metal is formed between the first substrate and the second substrate that are formed with the deep trench capacitors stacked on each other. Therefore, equivalent series resistance (ESR) of a capacitor can be reduced, and the device properties, such as switching speed, high band frequency properties, and the like can be improved.

Furthermore, according to the present disclosure, a pad metal is further formed on the second surface of the second substrate, and electrically connected to another pad metal between the first substrate and the second substrate, thereby reducing ESR of a capacitor and improving the device properties.

Meanwhile, it should be added that even if the effects are not explicitly mentioned herein, the effects described in the following specification expected by the technical features of the present disclosure and their potential effects can be treated as if they were described in the specifications of the present disclosure.

### BRIEF DESCRIPTION OF THE DRAWINGS

FIG. 1 is a sectional view illustrating a semiconductor device including a stacked deep trench capacitor structure according to an embodiment of the present disclosure;

FIG. 2 is an enlarged view of a first capacitor area according to FIG. 1;

FIG. 3 is an enlarged view of a second capacitor area according to FIG. 1; and

FIGS. 4 to 13 are reference views illustrating a method for manufacturing the semiconductor device including a stacked deep trench capacitor structure according to an embodiment of the present disclosure.

### DETAILED DESCRIPTION OF THE DISCLOSURE

Hereinbelow, embodiments of the present disclosure will be described in detail with reference to accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

In addition, although the terms first, second, etc. may be used to describe various items such as various elements, regions, and/or parts, the items should not be limited by these terms.

Furthermore, it should be noted that in cases where a specific embodiment can be implemented differently, a specific process sequence may be performed differently from the sequence described below. For example, the two processes described sequentially may be performed substantially simultaneously or may be performed in the opposite sequence.

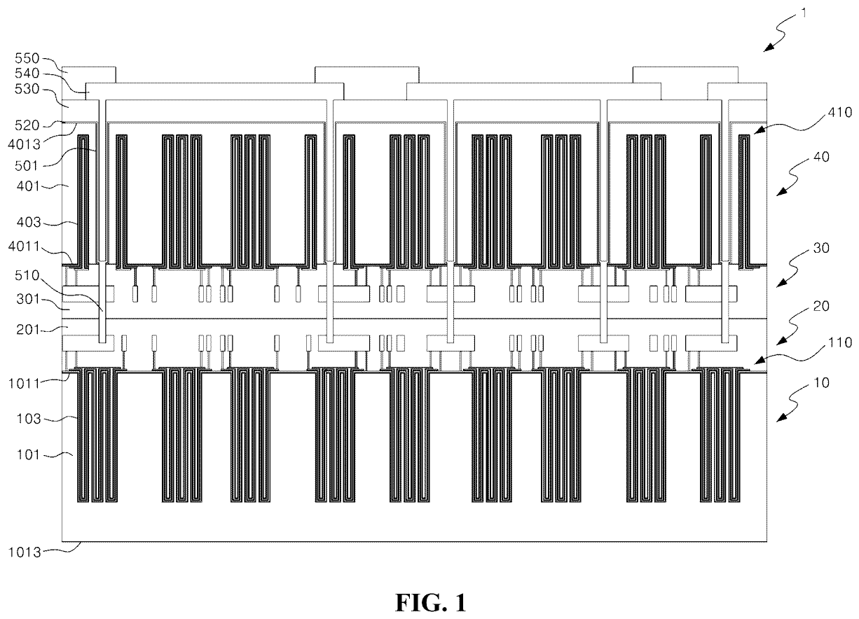

FIG. 1 is a sectional view illustrating a semiconductor device including a stacked deep trench capacitor structure according to an embodiment of the present disclosure.

Hereinbelow, with reference to accompanying drawings, a semiconductor device 1 including a stacked deep trench capacitor structure according to an embodiment of the present disclosure will be described in detail.

Referring to FIG. 1, the present disclosure relates to a semiconductor device 1 including a stacked deep trench capacitor structure and, more particularly, to a semiconductor device 1 including a stacked deep trench capacitor structure, wherein the semiconductor device 1 has a pad metal formed inside a capacitor area where a deep trench capacitor is formed, thereby reducing equivalent series resistance (ESR) of a capacitor and improving device properties such as switching speed, high band frequency properties, and the like.

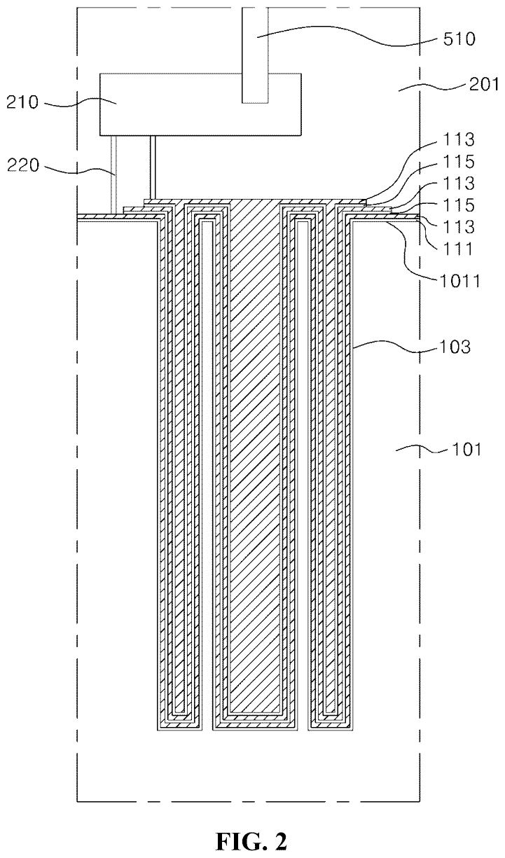

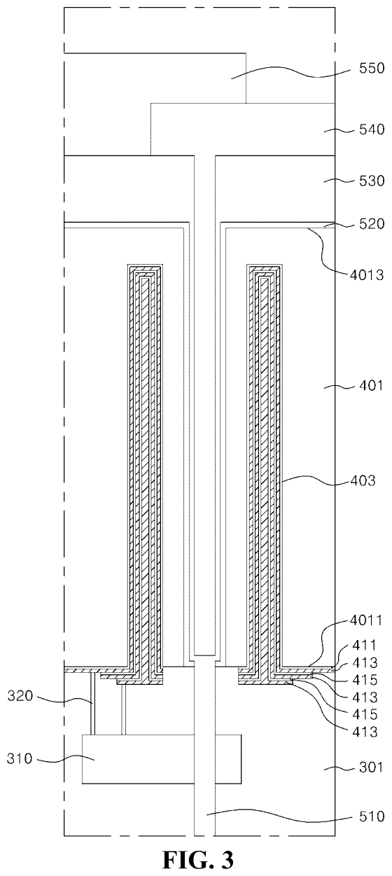

FIG. 2 is an enlarged view of a first capacitor area according to FIG. 1, and FIG. 3 is an enlarged view of a second capacitor area according to FIG. 1.

Referring to FIGS. 1 and 2, first, the semiconductor device 1 including a stacked deep trench capacitor structure may include a first capacitor area 10 including a first substrate 101. The first substrate 101 is formed below a second substrate 401, which will be described below, and may include a first surface 1011 facing the second substrate 401 and a second surface 1013 provided opposite to the first surface 1011. The first substrate 101 may be, for example, a silicon substrate.

Furthermore, a first deep trench 103 may be formed by extending to a predetermined depth in a direction from the first surface 1011 of the first substrate 101 to the second surface 1013. The first deep trench 103 may be formed by, for example, the reactive ion etching (RIE) method, but there is no limitation thereto. The first deep trench 103 may have a substantially uniform width size, a width gradually narrowed, or a width gradually widened, as it extends in the direction from the first surface 1011 to the second surface 1013 of the first substrate 101, but the scope of the present disclosure is not limited to any particular example.

Furthermore, a first deep trench capacitor 110 may be formed at the first deep trench 103 and a portion around the first deep trench 103. For example, a first buffer oxide film 111 may be formed on a bottom surface and inner side wall of the first deep trench 103, and the first buffer oxide film 111 may be, for example, a SiO2 film and be grown by the thermal oxidation process, but the scope of the present disclosure is not limited thereto. Furthermore, in the first deep trench 103, a first conductive layer 113 and a first dielectric layer 115 may be successively deposited on the first buffer oxide film 111. The first conductive layer 113 and the first dielectric layer 115 may have a structure in which multiple first conductive layers and dielectric layers are repeatedly stacked on each other in an upward direction, and multiple capacitors may be in a parallel connection to each other under the structure. The first conductive layer 113 may include, for example, TiN, TaN, W, and Poly Si layers. The first dielectric layer 115 may include, for example, an oxide film and be formed by, for example, the atomic layer deposition (ALD) process.

Referring to FIGS. 1 and 2, a first wiring area 20 may be formed on the first surface 1011 of the first substrate 101. The first wiring area 20 may include a first insulator film layer 201, a first pad metal 210, and a first contact plug 220.

The first insulator film layer 201 may include, for example, an insulator material such as a silicon oxide film, and the like. For example, the first insulator film layer 201 may be formed from an oxide film selected from a group consisting of BPSG, PSG, BSG, USG, TEOS, and HDP films, or a stacked film formed by stacking them into two or more layers.

Furthermore, the first pad metal 210 is formed in the first insulator film layer 201, and the first pad metal 210 may be electrically connected to the above-described first deep trench capacitor 110. In the drawings, the first pad metal 210 is shown to be formed in a single layer, and one or more layers of wiring layers, preferably, a multi-layered structural wiring layer (not shown) may be formed between each first pad metal 210 and the corresponding first deep trench capacitor 110. The first pad metal 210 may include, for example, an aluminum (Al) metal layer, and otherwise, may be a single-metal layer or a metal layer of an alloyed film including dissimilar metals.

Furthermore, each first pad metal 210, and the first contact plug 220 that electrically connects the corresponding wiring layer and the first deep trench capacitor 110 to each other may be provided in the first insulator film layer 201. The first contact plug 220 may be formed in the first insulator film layer 201 by the damascene process and, as an example, may be formed from at least one of impurity ion doped multicrystalline silicon films, metal films, or alloyed films with a mixture of dissimilar metals.

Furthermore, referring to FIGS. 1 and 3, a second wiring area 30 may be formed on the first wiring area 20. The second wiring area 30 may be positioned between the first wiring area 20 and a second capacitor area 40, which will be described below. The second wiring area 30 may have a sectional structure that is inverted upside down with the first wiring area 20, but the scope of the present disclosure is not limited thereto. The second wiring area 30 may include a second insulator film layer 301, a second pad metal 310, and a second contact plug 320.

The second insulator film layer 301 may include, for example, an insulator material such as a silicon oxide film, and the like. For example, the second insulator film layer 301 may be formed from an oxide film selected from a group consisting of BPSG, PSG, BSG, USG, TEOS, and HDP films, or a stacked film formed by stacking them into two or more layers.

Furthermore, the second pad metal 310 is formed in the second insulator film layer 301, and the second pad metal 310 may be electrically connected to a second deep trench capacitor 410, which will be described below. In the drawings, the second pad metal 310 is shown to be formed in a single layer, and one or more layers of wiring layers, preferably, a multi-layered structural wiring layer (not shown) may be formed between each second pad metal 310 and the corresponding second deep trench capacitor 410. The second pad metal 310 may include, for example, an aluminum (Al) metal layer, and otherwise, it is sufficient that the second pad metal 310 is a single-metal layer or a metal layer of an alloyed film including dissimilar metals.

Furthermore, each second pad metal 310, and the second contact plug 320 that electrically connects the corresponding wiring layer and the second deep trench capacitor 410 to each other may be provided in the second insulator film layer 301. The second contact plug 320 may be formed in the second insulator film layer 301 by the damascene process, and as an example, may be formed from at least one of impurity ion doped multicrystalline silicon films, metal films, or alloyed films with a mixture of dissimilar metals. As described above, according to the embodiment of the present disclosure, it is shown that the first pad metal 210 and the second pad metal 310 are horizontally formed in the capacitor areas 10 and 40 in the structure of stacking the first capacitor area 10 and the second capacitor area 40 on each other. Therefore, the equivalent series resistance (ESR) of a capacitor can be reduced.

Referring to FIGS. 1 and 3, the second capacitor area 40 may be formed on the second wiring area 30. The second capacitor area 40 may have, as an example, a sectional form inverted upside down with the first capacitor area 10, but the scope of the present disclosure is not limited thereto.

First, the second substrate 401 may be formed in the second capacitor area 40. The second substrate 401 may include a first surface 4011 facing the first substrate 101, and a second surface 4013 provided opposite to the first surface 4011. In other words, the first surface 4011 of the second substrate 401 may be formed directly above the second insulator film layer 301 below the first surface. Furthermore, the second substrate 401 may be, for example, a silicon substrate. Furthermore, a second deep trench 403 may be formed by extending to a predetermined depth in a direction from the second surface 4013 of the second substrate 401 to the second surface 4013. The second deep trench 403 may be formed by, for example, the reactive ion etching (RIE) method, but there is no limitation thereto. The second deep trench 403 may have a substantially uniform width size, a width gradually narrowed, or a width gradually widened, as it extends in the direction from the first surface 4011 to the second surface 4013 of the second substrate 401, but the scope of the present disclosure is not limited to any particular example.

Furthermore, a second deep trench capacitor 410 may be formed at the second deep trench 403 and a portion around the second deep trench 403. For example, a second buffer oxide film 411 may be formed on a bottom surface and an inner side wall of the second deep trench 403, and the second buffer oxide film 411 may be, for example, SiO2, and be grown by thermal oxidation, but the scope of the present disclosure is not limited thereto. Furthermore, in the second deep trench 403, a second conductive layer 413 and a second dielectric layer 415 may be successively deposited on the second buffer oxide film 411. The second conductive layer 413 and the second dielectric layer 415 may have a structure in which multiple first conductive layers and dielectric layers are repeatedly stacked on each other in the upward direction, and multiple capacitors may have a parallel connection to each other under the structure. The second conductive layer 413 may include, for example, TiN, TaN, W, and Poly Si layers. The second dielectric layer 415 may include, for example, an oxide film and may be formed by, for example, the atomic layer deposition (ALD) process.

Furthermore, referring to FIG. 1, a pad area 50 having a structure of penetrating the second capacitor area 40 may be formed on the second capacitor area 40. The pad area 50 may include a via hole 501, a through silicon via (TSV) 510, a third insulator film layer 520, a connection metal 530, and a third pad metal 540.

The via hole 501 extends from the first surface 4011 of the second substrate 401 to the second surface 4013 and thus penetrates the second substrate 401 in a vertical direction. The via hole 501 may extend in the vertical direction longer than the second deep trench 403. Furthermore, the via hole 501 may have a width larger than the width of the second deep trench 403, but the scope of the present disclosure is not limited thereto.

The TSV 510 extends downwards from an inner portion of the via hole 501 or a lower portion of the via hole 501 and is physically connected to the corresponding first pad metal 210 and the corresponding second pad metal 310. The TSV 510 may penetrate the second insulator film layer 301 and extend to a predetermined depth in the first insulator film layer 201. Furthermore, the TSV 510 may include, for example, W, but the scope of the present disclosure is not limited thereto. The TSV 510 may allow the corresponding third pad metal 540 to be electrically connected to the corresponding first pad metal 210 and the corresponding second pad metal 310 in the vertical direction.

The third insulator film layer 520 is an insulator film formed on the second surface 4013 of the second substrate 401 and may include, for example, an oxide film, but the scope of the present disclosure is not limited thereto. The third insulator film layer 520 may be formed between the second substrate 401 and the connection metal 530, which will be described below. Furthermore, the third insulator film layer 520 may be formed on the bottom surface of the via hole 501. At this point, the third insulator film layer 520 may be formed to cover only a partial area of the bottom surface of the via hole 501. Therefore, the TSV 510 may be electrically connected to the connection metal 530 and the third pad metal 540. In other words, at the lower portion of the via hole 501, the TSV 510 may have a sectional structure of penetrating the third insulator film layer 520.

The connection metal 530 is positioned on the third insulator film layer 520 on the inner side wall of the via hole 501 and, as an example, may include W. The connection metal 530 may also be formed on the third insulator film layer 520 on the second surface 4013 of the second substrate 401. The connection metal 530 may also be integrally formed with the TSV, but the scope of the present disclosure does not have any limitation.

Furthermore, to gap-fill the inner portion of the via hole 501, the third pad metal 540 may be formed on the connection metal 530. The third pad metal 540 may also be formed on the connection metal 530 on the third insulator film layer 520, in addition to the inner portion of the via hole 501. As described above, according to the embodiment of the present disclosure, it is shown that the first pad metal 210 and the second pad metal 310 are horizontally formed in the capacitor areas 10 and 40 in the structure of stacking the first capacitor area 10 and the second capacitor area 40 on each other, and the third pad metal 540 may also be formed on the second surface 4013 of the second substrate 401. Therefore, the equivalent series resistance (ESR) of the capacitor can be reduced.

Furthermore, a passivation layer 550 configured to be an insulator film may be formed between the third pad metal 540 and an adjacent third pad metal 540. A bottom surface of the passivation layer 550 may be positioned on the connection metal 530 and the third pad metal 540.

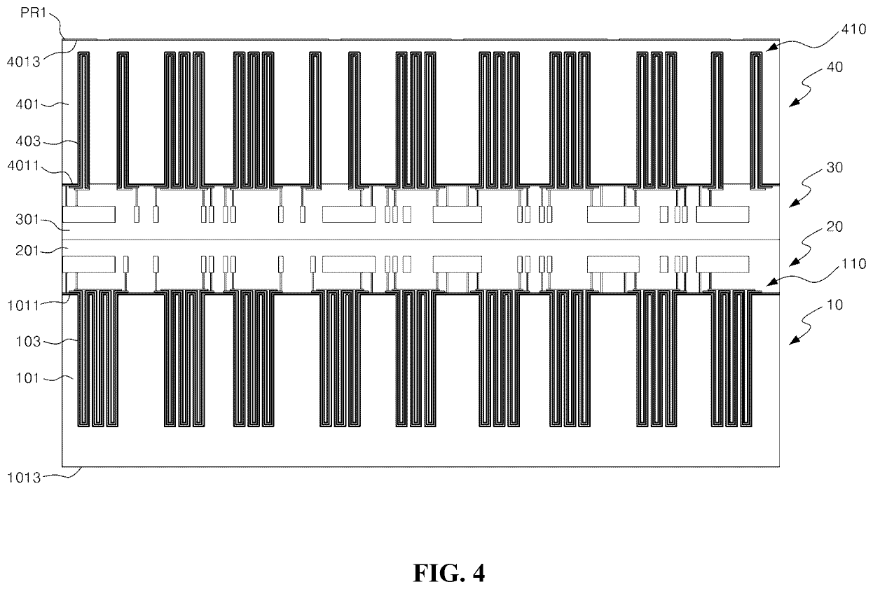

FIGS. 4 to 13 are reference views illustrating a method for manufacturing the semiconductor device including a stacked deep trench capacitor structure according to an embodiment of the present disclosure.

Hereinbelow, with reference to accompanying drawings, the method of manufacturing a semiconductor device including a deep trench capacitor structure according to an embodiment of the present disclosure will be described in detail. Hereinbelow, the process of forming the pad area 50 will be mainly described. Before the formation of the pad area 50, one of the back grinding process, the thinning process, the wet etching process, or the CMP process for the second surface 4013 of the second substrate 401 may be performed, but the scope of the present disclosure is not limited thereto.

Referring to FIG. 4, a first mask pattern PR1 may be formed first on the second surface 4013 of the second substrate 401. On the second surface 4013 of the second substrate 401, the first mask pattern PR1 may be formed by opening a portion of the second surface 4013 of the second substrate 401, which is provided at the portion corresponding to the portion where the via hole 501 is formed.

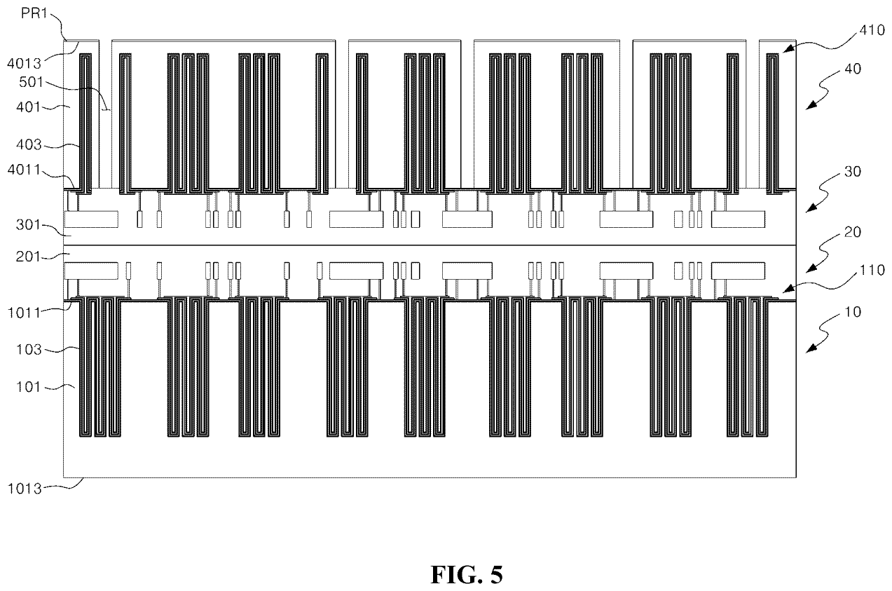

Referring to FIG. 5, thereafter, the etching process for the second substrate 401 is performed by using the first mask pattern PR1 so that the via hole 501 may be formed in the second substrate 401. The via hole 501 may be formed so that a portion of an upper surface of the second insulator film layer 301 is partially exposed. After the formation of the via hole 501, the first mask pattern PR1 may be removed.

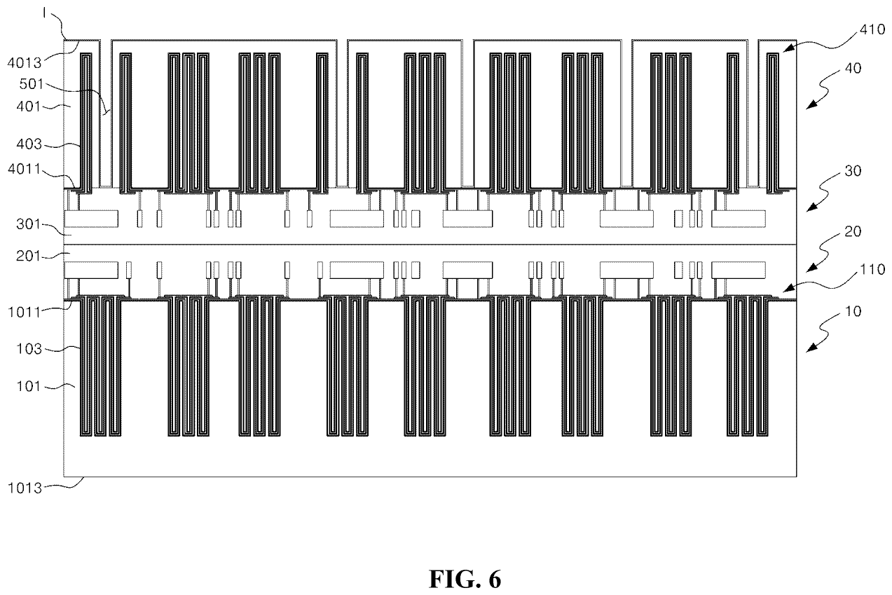

Referring to FIG. 6, an insulator film I may then be deposited on the second surface 4013 of the second substrate 401 and along the inner side wall of the via hole 501. The insulator film I may be formed not only on the inner side wall of the via hole 501 but also on an upper surface of the second insulator film layer 301 below the via hole 501.

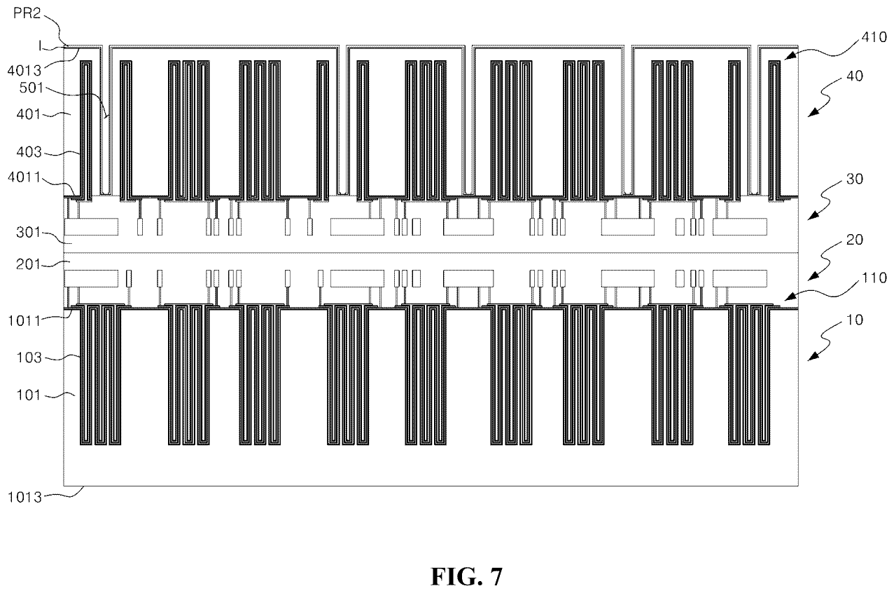

Referring to FIG. 7, a second mask pattern PR2 may be formed on the insulator film I on the second surface 4013 of the second substrate 401. The second mask pattern PR2 may be formed on the insulator film I on the second surface 4013 of the second substrate 401, and on the insulator film I on the inner side wall of the via hole 501. Furthermore, the second mask pattern PR2 may be formed on the insulator film I on the second insulator film layer 301, and may be formed to open the insulator film I at the portion corresponding to the portion where the TSV 501 is formed.

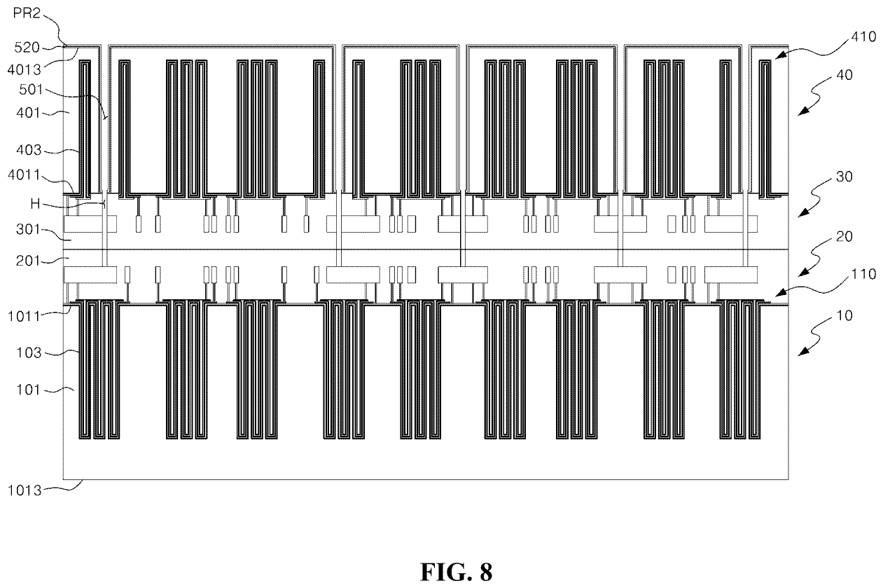

Referring to FIG. 8, as the etching process for the first insulator film layer 201 and the second insulator film layer 301 is then performed by using the second mask pattern PR2, a via hole H may be formed in the first insulator film layer 201 and the second insulator film layer 301. Hereinbelow, the via hole H formed by the process will be referred to as “the second via hole”, and the via hole 501 described above will be referred to as “the first via hole”. The second via hole H communicates with the first via hole 501 and may have the width narrower than the width of the first via hole 501. Furthermore, a portion of an upper surface of a first pad metal 201 in the first insulator film layer 201 may be exposed through the second via hole H. Through the process, the insulator film I may include the above-described structure of the third insulator film layer 520. After the process, the second mask pattern PR2 may be removed.

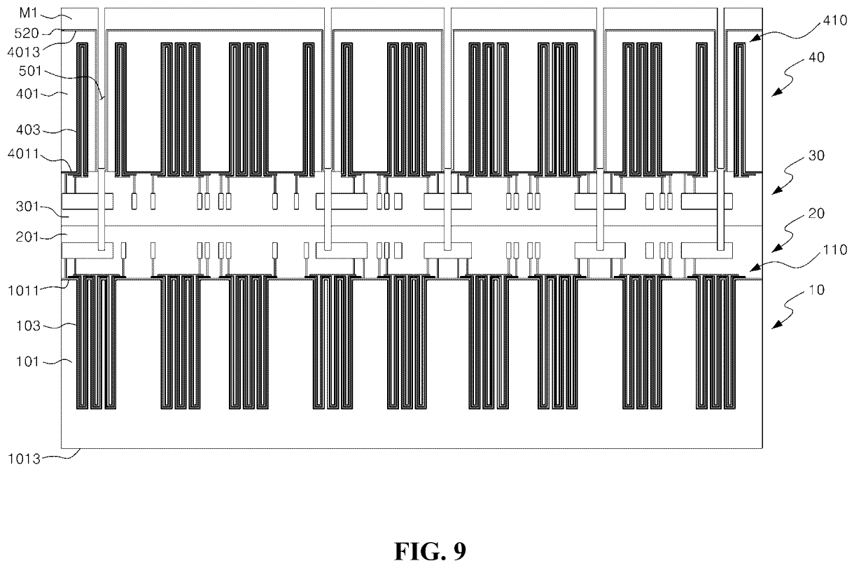

Referring to FIG. 9, after the formation of the second via hole H, a first metal layer M1 in the second via hole H may be filled. Furthermore, the first metal layer M1 may be formed on the third insulator film layer 520 on the inner side wall of the first via hole 501, and may also be formed on the second surface 4013 of a fourth substrate 401. At this point, the first metal layer M1 filled in the second via hole H may have the structure of the TSV 510 on the third insulator film layer 520 on the inner side wall of the first via hole 501, and the first metal layer M1 formed on the second surface 4013 of the fourth substrate 401 may have the structure of the connection metal 530.

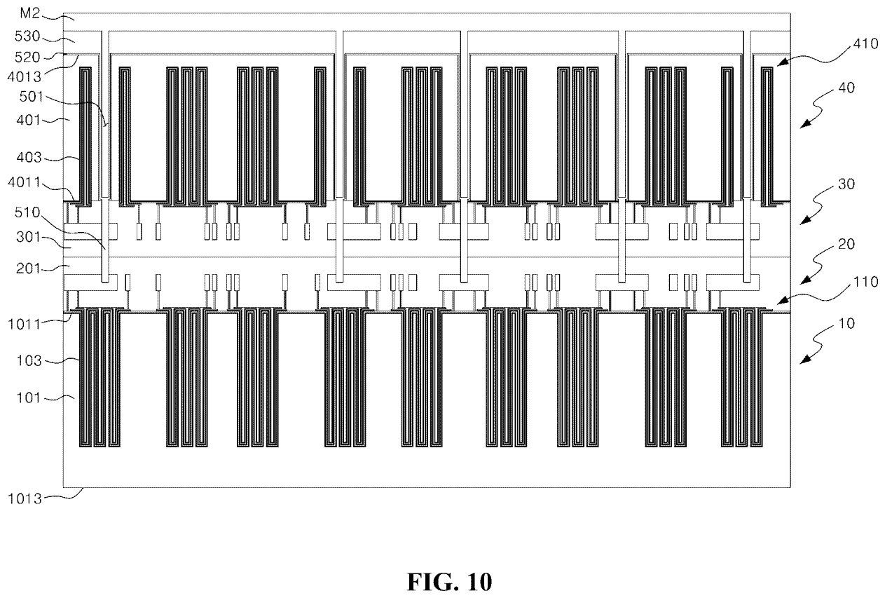

Referring to FIG. 10, a second metal layer M2 may then be gap-filled in the first via hole 501. For example, the second metal layer M2 may be formed on the connection metal 530 in the first via hole 501, and may also be formed on the connection metal 530 on the second surface 4013 of the fourth substrate 401.

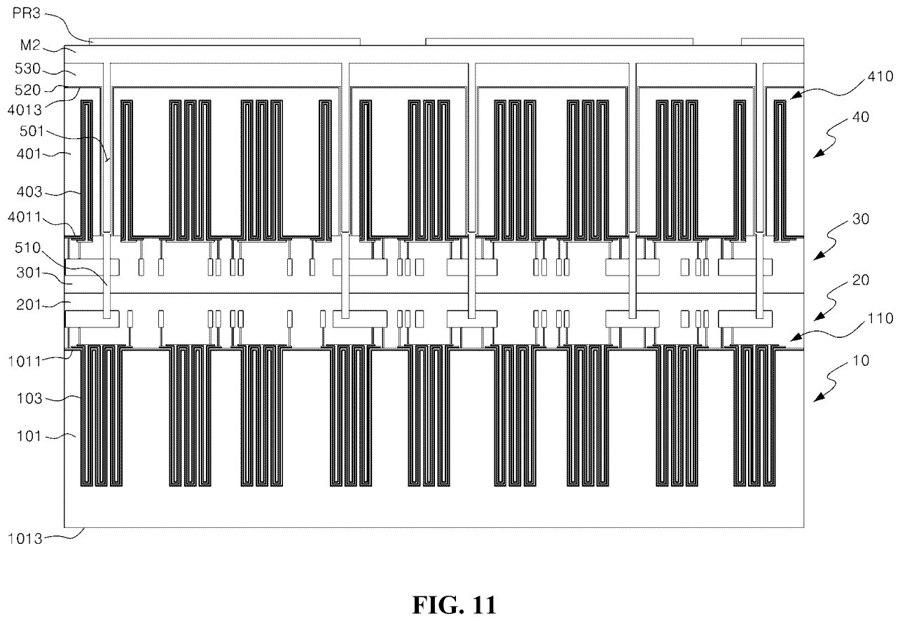

Referring to FIG. 11, a third mask pattern PR3 may be formed on the second metal layer M2 as a following process. The third mask pattern PR3 may be formed so that a specific area of the second metal layer M2 is opened outwards.

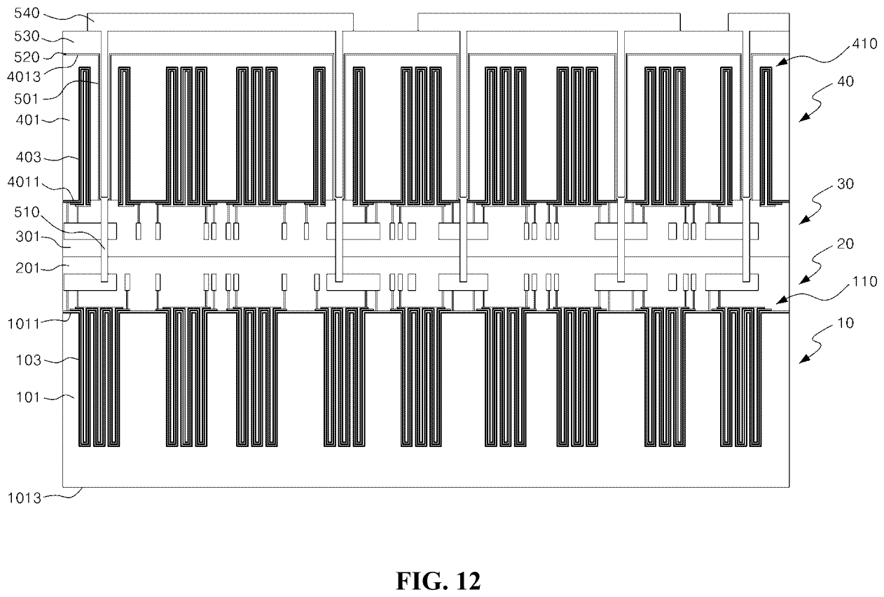

Referring to FIG. 12, thereafter, the etching process for the second metal layer M2 is performed by using the third mask pattern PR3 so that the third pad metal 540 may be completed. After the process, the third mask pattern PR3 may be removed.

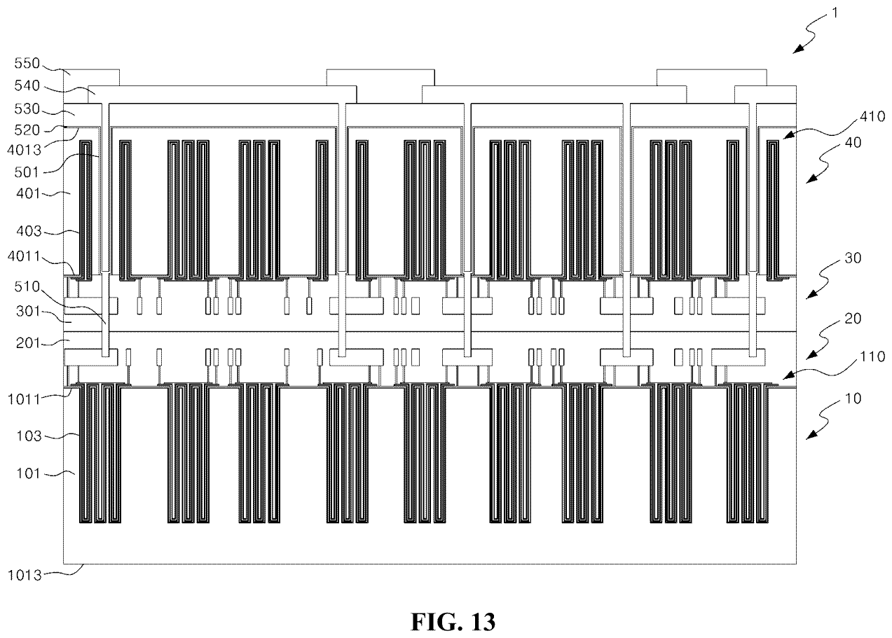

Referring to FIG. 13, finally, the passivation layer 550 may be formed between the third pad metal 540 and another adjacent third pad metal 540.

The detailed description above is illustrative of the present disclosure. In addition, the above description shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiments describe the best state for implementing the technical spirit of the present disclosure, and various changes required in the specific application field and use of the present disclosure are possible. Accordingly, the detailed description of the present disclosure is not intended to limit the present disclosure to the disclosed embodiments.

What is claimed is:

1. A semiconductor device including a deep trench capacitor, the semiconductor device comprising:
a first capacitor area;
a first wiring area disposed on the first capacitor area;
a second wiring area disposed on the first wiring area; and
a second capacitor area disposed on the second wiring area,
wherein the first capacitor area comprises:
a first substrate comprising a first surface and a second surface disposed opposite to each other; and
a first deep trench capacitor disposed at the first substrate, and
wherein the second capacitor area comprises:
a second substrate comprising a first surface and a second surface disposed opposite to each other; and
a second deep trench capacitor disposed at the second substrate.

2. The semiconductor device of claim 1, wherein the first wiring area comprises:
a first insulator film layer;
a first pad metal disposed in the first insulator film layer; and
a first contact plug disposed in the first insulator film layer and electrically connecting the first pad metal and the first deep trench capacitor to each other.

3. The semiconductor device of claim 2, wherein the second wiring area comprises:
a second insulator film layer;
a second pad metal disposed in the second insulator film layer; and
a second contact plug disposed in the second insulator film layer and electrically connecting the second pad metal and the second deep trench capacitor to each other.

4. The semiconductor device of claim 3, further comprising:
a pad area disposed on the second capacitor area.

5. The semiconductor device of claim 4, wherein the pad area comprises one portion connected to both the first pad metal and the second pad metal.

6. The semiconductor device of claim 4, wherein the pad area comprises:
a via hole penetrating the second substrate in a vertical direction;
a through silicon via (TSV) extending downwards from an inner portion or a lower portion of the via hole and connected to both the first pad metal and the second pad metal; and
a third pad metal filling the inner portion of the via hole.

7. The semiconductor device of claim 6, wherein the via hole has a greater width than a width of a deep trench of the second deep trench capacitor.

8. The semiconductor device of claim 6, wherein the pad area further comprises:
a third insulator film layer disposed on an inner side wall and a bottom surface of the via hole, the third insulator film layer being disposed between the third pad metal and the inner side wall of the via hole.

9. The semiconductor device of claim 8, wherein the third insulator film layer covers a portion of an upper surface of the second insulator film layer exposed at the lower portion of the via hole.

10. The semiconductor device of claim 8, wherein the pad area further comprises:
a connection metal disposed on the third insulator film layer and connected to the TSV.

11. A semiconductor device including a deep trench capacitor, the semiconductor device comprising:
a first substrate having a first surface and a second surface, the first surface being disposed opposite to the second surface;
a first deep trench extending from the first surface toward the second surface;
a first conductive layer disposed in the first deep trench;
a first dielectric layer disposed on the first conductive layer in the first deep trench;
a first insulator film layer disposed on the first substrate;
a first pad metal and a second pad metal stacked on each other in the first insulator film layer;
a second substrate disposed on the first insulator film layer and having a first surface and a second surface, the first surface of the second substrate being disposed opposite to the second surface of the second substrate;
a second deep trench extending from the first surface of the second substrate toward the second surface of the second substrate;
a second conductive layer disposed in the second deep trench; and
a second dielectric layer disposed on the second conductive layer,
wherein the first pad metal is connected to the first conductive layer, and the second pad metal is connected to the second conductive layer.

12. The semiconductor device of claim 11, further comprising:
a via hole penetrating the second substrate;
a second insulator film layer disposed on the second substrate;
a third pad metal disposed on the second insulator film layer, and inside the via hole; and
a TSV extending downwards from an inner portion or a lower portion of the via hole.

13. The semiconductor device of claim 12, wherein the TSV is connected to both the first pad metal and the second pad metal.

14. The semiconductor device of claim 13, further comprising:
a passivation layer disposed in contact with the third pad metal on the second surface of the second substrate.

15. The semiconductor device of claim 13, wherein the TSV extends to a position between an upper surface of the second insulator film layer on the second substrate and the third pad metal.

16. A method for manufacturing a semiconductor device including a stacked deep trench capacitor structure, wherein the semiconductor device includes a first capacitor area including a first substrate, a first wiring area including a first insulator film layer and provided on the first capacitor area, a second wiring area including a second insulator film layer and provided on the first wiring area, and a second capacitor area including a second substrate and provided on the second wiring area, the method comprising:
forming a first via hole on the second substrate by etching the second substrate;
forming an insulator film layer on an upper surface of the second substrate and an inner side wall of the first via hole;
forming a TSV in the first insulator film layer and the second insulator film layer at a lower portion the first via hole; and
forming a first pad metal on the second capacitor area.

17. The semiconductor device of claim 16, wherein the forming of the TSV includes:
forming a second via hole in the first insulator film layer and the second insulator film layer; and
gap-filling with a metal layer in the second via hole.

18. The semiconductor device of claim 16, wherein the TSV is connected to a second pad metal formed in each of the first insulator film layer and the second insulator film layer.

19. The semiconductor device of claim 16, wherein the first pad metal extends to an inner portion of the first via hole and is connected to the TSV.

20. The semiconductor device of claim 17, wherein the second via hole has a width smaller than a width of the first via hole.
